(19) United States
(12) Patent Application Publication
(10) Pub. No.: US 2013/0228842 A1
(43) Pub. Date: Sep. 5, 2013

(54) SEMICONDUCTOR STORAGE DEVICE AND MANUFACTURING METHOD THEREOF

(71) Applicants: Takahiro Kotou, Yokkaichi-Shi (JP); Hideto Takekida, Nagoya-Shi (JP); Minori Kajimoto, Fujisawa-Shi (JP)

(72) Inventors: Takahiro Kotou, Yokkaichi-Shi (JP); Hideto Takekida, Nagoya-Shi (JP); Minori Kajimoto, Fujisawa-Shi (JP)

(73) Assignee: Kabushiki Kaisha Toshiba, Tokyo (JP)

(21) Appl. No.: 13/601,076

(22) Filed: Aug. 31, 2012

(30) Foreign Application Priority Data
Sep. 20, 2011 (JP) 2011-204910

(51) Int. Cl. H01L 29/788; H01L 21/28

(52) U.S. Cl. CPC H01L 29/7889; H01L 21/28273
USPC 257/315; 438/587

(57) ABSTRACT

A semiconductor storage device includes a semiconductor substrate. A first insulating film is provided on the semiconductor substrate. A charge storage layer includes a first part provided on the first insulating film, an intermediate insulating film provided on the first part, and a second part provided on the intermediate insulating film, and is capable of storing electric charges. A second insulating film is provided on an upper surface and a side surface of the charge storage layer. A control gate is opposed to the upper surface and the side surface of the charge storage layer via the second insulating film, and is configured to control a voltage of the charge storage layer. The intermediate insulating film is recessed in comparison with side surfaces of the first and second parts on the side surface of the charge storage layer.

### CROSS REFERENCE TO RELATED APPLICATIONS

This application is based upon and claims the benefit of priority from the prior Japanese Patent Application No. 2011-204910, filed on Sep. 20, 2011, the entire contents of which are incorporated herein by reference.

### FIELD

The embodiments of the present invention relate to a semiconductor storage device and manufacturing method thereof.

### BACKGROUND

There has been known a NAND flash EEPROM as a nonvolatile semiconductor storage device that is electrically rewritable and that can achieve high integration. Each memory cell transistor in a NAND flash EEPROM has a stacked gate structure including a floating gate (hereinafter, simply “FG”) storing electric charges and a control gate (hereinafter, simply “CG”) controlling a voltage of the FG.

It is desirable that a voltage applied to a CG can be efficiently transmitted to an FG so as to improve the memory cell characteristics. As a result of the efficient transmission of the voltage, the voltage difference between the FG and a semiconductor substrate becomes large as the voltage of the FG largely changes, and therefore a data writing speed and a data erasing speed are accelerated. Furthermore, it is also possible to suppress erroneous data writing because the voltage of the CG can exercise favorable control over the voltage of the FG.

The coupling capacitance ratio of the CG to the FG is known as an index that indicates the control performance of the voltage of the CG over the voltage of the FG.

It suffices to increase an opposed area by the CG is opposed to the FG so as to increase the coupling capacitance ratio. In order to increase the opposed area, the CG is formed to be opposed not only on an upper surface of the FG but also a side surface thereof. For further increasing the coupling capacitance ratio, it is proposed to bury the CG down to a deep (low) position between the two adjacent FGs and to increase the opposed area by which the CG is opposed to the side surface of the FG.

However, along with the downscaling of elements, the aspect ratio of a trench between adjacent FGs becomes higher. Therefore, it is not easy to completely bury the CG down to a deep position between adjacent FGs, and seams or voids occur in the CG in some cases. These seams or voids, in turn, cause a decrease in the coupling capacitance ratio of the CG to the FG, resulting in degraded writing characteristics and writing irregularity among memory cells. Furthermore, if the CG is buried down to a deep position between adjacent FGs, the distance between the CG and the semiconductor substrate becomes close. This disadvantageously and possibly damages an oxide film between the CG and the semiconductor substrate and generates a leakage current.

### BRIEF DESCRIPTION OF THE DRAWINGS

FIG. 1 is a schematic diagram showing a configuration of a memory cell array in a NAND flash EEPROM according to a first embodiment;

FIG. 2 is a cross-sectional view of one NAND string NS;

FIG. 3 is a cross-sectional view showing a configuration of the memory cells MC;

FIGS. 4 to 9 are cross-sectional views showing a method of manufacturing the NAND flash EEPROM according to the first embodiment; and

FIG. 10 is a cross-sectional view showing a configuration of memory cells MC in a NAND flash EEPROM according to a second embodiment.

### DETAILED DESCRIPTION

A semiconductor storage device according to the present embodiment includes a semiconductor substrate. A first insulating film is provided on the semiconductor substrate. A charge storage layer includes a first part provided on the first insulating film, an intermediate insulating film provided on the first part, and a second part provided on the intermediate insulating film, and is capable of storing electric charges. A second insulating film is provided on an upper surface and a side surface of the charge storage layer. A control gate is opposed to the upper surface and the side surface of the charge storage layer via the second insulating film, and is configured to control a voltage of the charge storage layer. The intermediate insulating film is recessed in comparison with side surfaces of the first and second parts on the side surface of the charge storage layer.

Embodiments will now be explained with reference to the accompanying drawings. The present invention is not limited to the embodiments. In the following embodiments, terms such as “upper” or “lower” indicating a direction are to indicate a relative direction while assuming a surface of a silicon substrate 11 on which memory cells MC are provided as an upper surface. The upper direction often differs from an upper direction relative to a gravitational acceleration direction.

### First Embodiment

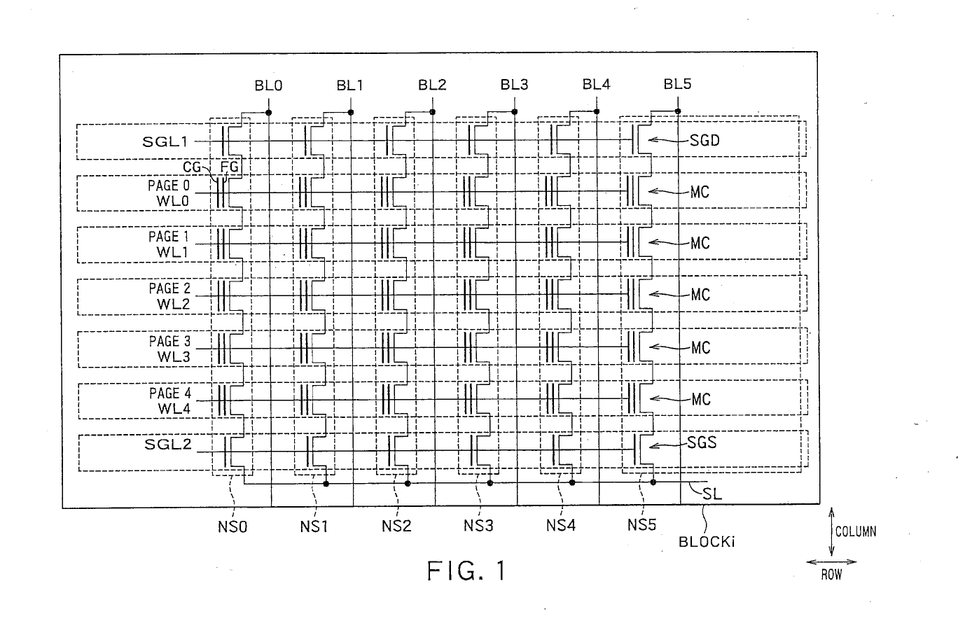

FIG. 1 is a schematic diagram showing a configuration of a memory cell array in a NAND flash EEPROM according to a first embodiment. The memory cell array includes a plurality of blocks BLOCK. FIG. 1 shows a configuration of a certain block BLOCKi (i is an integer). The block BLOCKi is a unit of data erasing and includes a plurality of NAND strings NS0 to NS5 (hereinafter, also generically “NS”) connected to bit lines BL in respective columns. Each of the NAND strings NS0 to NS5 includes a plurality of memory cells MC connected in series and select gate transistors SGS and SGD connected to both ends of these series-connected memory cells MC, respectively. While five memory cells MC are connected in series per NAND string NS in an example shown in FIG. 1, 32 or 64 memory cells MC are generally connected in series per NAND string NS. One end of each of the NAND strings NS0 to NS5 is connected to one of corresponding bit lines BL0 to BL5 and the other end thereof is connected to a common source line SL.

A control gate CG of each memory cell MC is connected to one of word lines WL0 to WL5 in a page to which the memory cell MC belongs. For example, the control gate CG of one memory cell MC belonging to a page j (j=0 to 4) is connected to a word line WLj. Gates of the select gate transistors SGD and SGS are connected to select gate lines SGL1 and SGL2, respectively. The page is a unit of data reading or data writing.

A plurality of word lines WL extend in a row direction, and a plurality of bit lines BL extend in a column direction so as to be substantially orthogonal to the row direction.

As shown in FIG. 1, the memory cells MC are provided to correspond to grid-like cross-points, respectively constituted by the word lines WL and active areas AA, to be described later, provided in parallel to the bit lines BL. For example, the grid-like cross-points constituted by the word lines WL0 to WL4 and the active areas AA provided in parallel to the bit lines BL0 to BL5 are located in a 5×6 matrix. The memory cells MC are arranged two-dimensionally to correspond to these cross-points in the 5×6 matrix, respectively. While the block BLOCKi according to the first embodiment includes 5×6 (=30) memory cells MC, the number of memory cells MC per block BLOCKi is not limited to 30.

As each of the memory cells MC, an n-FET (Field-Effect Transistor) including a floating gate FG (charge storage layer) and the control gate CG can be used. By applying a voltage to the control gate CG from one word line WL, electric charges (electrons) are charged into the floating gate FG or discharged from the floating gate FG. With this configuration, data is written to or erased from the memory cell MC. The memory cell MC has a threshold voltage proportional to the number of charges (electrons) stored in the floating gate FG. The memory cell MC can electrically store therein binary data (one bit) or multilevel data (two or more bits) as a difference from the threshold voltage.

As the memory cells MC, charge-storing nonvolatile memory cells can be used.

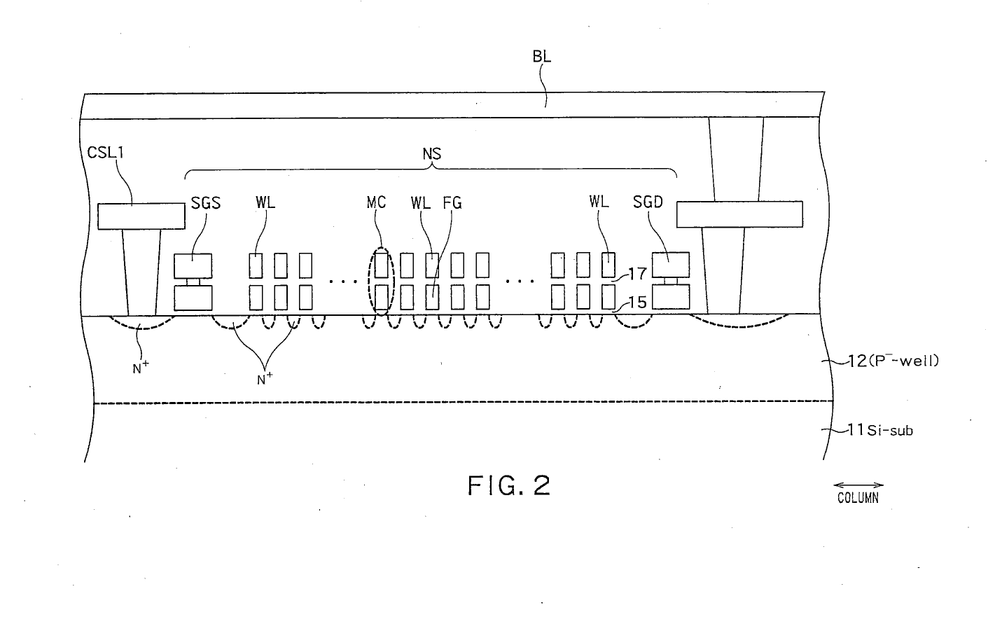

FIG. 2 is a cross-sectional view of one NAND string NS. The NAND string NS is formed on a P-well 12 formed on the silicon substrate 11. A first cell source line CSL1 is connected to the source-side select gate transistor SGS connected to a source side of the NAND string NS. The bit line BL is connected to the drain-side select gate transistor SGD connected to a drain side of the NAND string NS.

A plurality of memory cells MC adjacent in the column direction share n⁺ diffusion layers. The memory cells MC are thereby connected in series between the select gate transistors SGS and SGD.

Each of the memory cells MC includes the floating gate FG provided on the silicon substrate 11 via a tunnel gate insulating film 15, and the control gate CG provided on the floating gate FG via an IPD (Inter-Poly Dielectric) film 17.

Gate electrodes of the select gate transistors SGS and SGD are made of the same material as that of the floating gate FG and the control gate CG of each of the memory cells MC. However, in the select gate transistors SGS and SGD, the IPD film 17 between the floating gate FG and the control gate CG is partially eliminated to electrically connect the floating gate FG to the control gate CG.

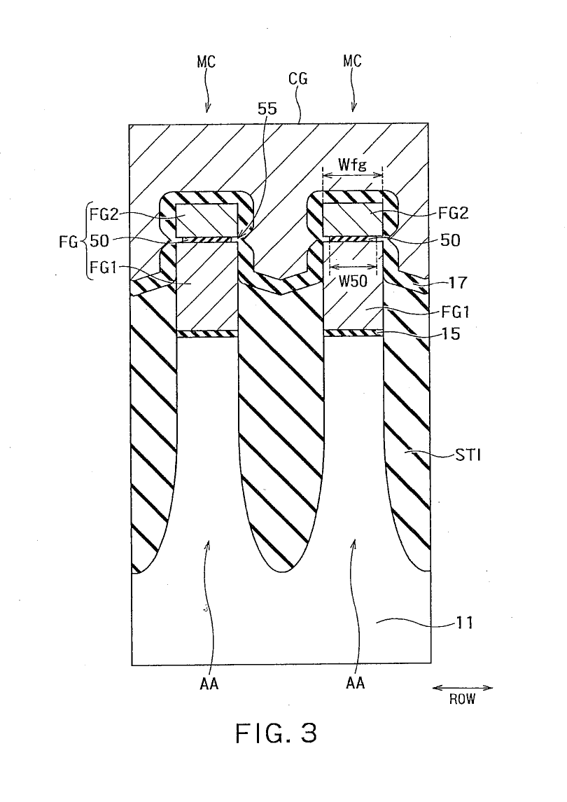

FIG. 3 is a cross-sectional view showing a configuration of the memory cells MC. FIG. 3 shows a cross-section of the memory cells MC in the row direction (cross-sections taken along one word line WL), and the cross-section shown in FIG. 3 is taken in a perpendicular direction to the drawing of FIG. 2.

An element isolation region STI (Shallow Trench Isolation) extending in the column direction is provided on the silicon substrate 11, and the active areas AA are formed between a plurality of the element isolation regions STI adjacent in the row direction. The active areas AA extending in the column direction are thereby arranged in stripes. A plurality of memory cells MC formed on each of the active areas AA constitute one NAND string NS. The element isolation regions STI isolate a plurality of NAND strings NS adjacent in the row direction from one another.

Each of the memory cells MC includes the tunnel gate insulating film 15, the floating gate FG, the IPD film 17, and the control gate CG. The tunnel gate insulating film 15 serving as a first insulating film is formed on the silicon substrate 11. The floating gate FG includes the tunnel gate insulating film 15, a first floating gate part FG1 (first part), a second floating gate part FG2 (second part), and an intermediate insulating film 50. The first floating gate part FG1 is provided on the tunnel gate insulating film 15. The intermediate insulating film 50 is provided on the first floating gate part FG1. The second floating gate part FG2 is provided on the intermediate insulating film 50. The floating gate FG, a voltage of which is controlled by the control gate CG, can trap charges (electrons, for example) via the tunnel gate insulating film 15 and store the charges. Conversely, the floating gate FG can emit the charges (electrons, for example) via the tunnel gate insulating film 15. The memory cell MC can thereby store therein binary data or multilevel data. For example, each of the first and second floating gate parts FG1 and FG2 is formed using a conductive film made of doped polysilicon or the like. For example, each of the tunnel gate insulating film 15 and the intermediate insulating film 50 is formed using an insulating film such as a silicon oxide film.

An upper surface and a part of a side surface of the floating gate FG are covered with the IPD film 17 serving as a second insulating film. For example, the IPD film 17 is formed using a silicon oxide film, a silicon nitride film, or an insulating film such as a High-k film higher in a dielectric constant than the silicon oxide film.

The control gate CG is opposed to the upper surface and a part of the side surface of the floating gate FG via the IPD film 17 so as to control the voltage of the floating gate FG. For example, the control gate CG is formed using a conductive film made of doped polysilicon, silicide or the like.

On the side surface of the floating gate FG, the intermediate insulating film 50 is recessed from (in comparison with) the side surface of the first and second floating gate parts FG1 and FG2. That is, a width W50 of the intermediate insulating film 50 in the row direction is smaller than a width Wfg of each of the first and second floating gate parts FG1 and FG2 in the row direction. As a result, the floating gate FG includes recesses (constrictions) 55 on the side surface thereof. The IPD film 17 is also recessed along with the intermediate insulating film 50 on the side surface of the floating gate FG along the recesses 55 of the floating gate FG.

The control gate CG is provided to reach a deeper position than that of the intermediate insulating film 50 on the side surface of the floating gate FG. In other words, the element isolation regions STI under the control gate CG are etched back to a position lower than that of the intermediate insulating film 50.

The control gate CG is inserted into recesses of the IPD film 17 and protrudes toward the side surface of the floating gate FG in proportion to the intermediate insulating film 50. The presence of the recesses 55 can thereby increase the opposed area by which the floating gate FG is opposed to the control gate CG.

Generally, a coupling capacitance ratio Cr of the floating gate FG to the control gate CG is represented by the following Equation (1).

Cr=Cipd/(Cipd+Cox) (1)

where Cipd indicates a capacitance of the IPD film 17 and Cox indicates a capacitance of the tunnel gate insulating film 15. The increased capacitance Cipd of the IPD film 17 can increase the coupling capacitance ratio Cr. Examples of means for increasing the capacitance Cipd of the IPD film 17 include making the IPD film 17 thinner and increasing the opposed area between the floating gate FG and the control gate CG.

According to the first embodiment, the presence of the recesses 55 can increase the opposed area by which the floating gate FG is opposed to the control gate CG, and can increase the coupling capacitance ratio Cr, accordingly. In the memory, that is, NAND flash EEPROM according to the first embodiment, it is possible to increase the coupling capacitance ratio Cr without the need to form each control gate CG down to a deep (low) position between the adjacent floating gates FG. That is, according to the first embodiment, the coupling capacitance ratio Cr can be increased even when the control gate CG remains shallow between the adjacent floating gates FG. As a result, according to the first embodiment, it is possible to suppress the occurrence of seams or voids in the control gate CG.

Furthermore, if the control gate CG is shallow between the adjacent floating gates FG, this follows that there is a large distance between the control gate CG and the silicon substrate 11. Therefore, according to the first embodiment, it is possible to suppress the occurrence of a leakage current between the control gate CG and the silicon substrate 11.

Further, the insertion of the very thin intermediate insulating film 50 into each of the floating gates FG can generate a barrier between the first and second floating gate parts FG1 and FG2. This barrier can suppress the transfer of the charges (electrons) between the first and second floating gate parts FG1 and FG2 to some extent. This configuration can contribute to improving the charge retention capability of the memory cell MC.

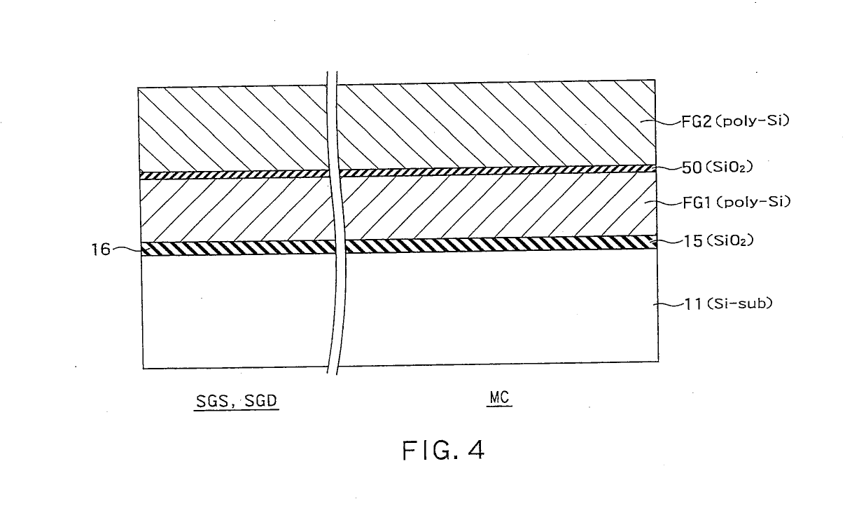

FIGS. 4 to 9 are cross-sectional views showing a method of manufacturing the NAND flash EEPROM according to the first embodiment. In each of FIGS. 4 to 9, a right side shows the cross-section of the memory cells MC and a left side shows a cross-section of each of the select gate transistors SGS and SGD.

First, the tunnel gate insulating film 15 is formed on the silicon substrate 11. For example, a silicon oxide film is used as the tunnel gate insulating film 15, and the silicon oxide film can be formed by oxidizing the silicon substrate 11. A gate insulating film for the select gate transistors SGS and SGD can be formed in regions in which the select gate transistors SGS and SGD are to be formed, apart from the tunnel gate insulating film 15. In the following explanations, the gate insulating film for the select gate transistors SGS and SGD are referred to as “the gate insulating film 16”.

Next, the material of the first floating gate part FG1 is deposited on the tunnel gate insulating film 15. The material of the first floating gate part FG1 is amorphous silicon, for example.

The intermediate insulating film 50 is then formed on the first floating gate part FG1 by exposing the material of the first floating gate part FG1 to oxygen and oxidizing a surface of the material. Thereafter, the material of the second floating gate part FG2 is deposited on the intermediate insulating film 50. Similarly to the first floating gate part FG1, the material of the second floating gate part FG2 is amorphous silicon, for example.

After film formation, a heat treatment is carried out on the amorphous silicon as the materials of the first and second floating gate parts FG1 and FG2, thereby changing composition from the amorphous silicon to polysilicon. The materials of the first and second floating gate parts FG1 and FG2 that are polysilicon films can be thereby formed uniformly on the tunnel gate insulating film 15.

The first floating gate part FG1, the intermediate insulating film 50, and the second floating gate FG2 can be continuously formed in the same chamber. Alternatively, after forming the first floating gate part FG1, the intermediate insulating film 50 can be formed by taking out the silicon substrate 11 from the chamber and exposing the first floating gate part FG1 to the air. After returning the silicon substrate 11 into the chamber, the second floating gate part FG2 can be formed. In this case, the intermediate insulating film 50 is formed by natural oxide. As a result, a structure shown in FIG. 4 can be obtained.

As the intermediate insulating film 50, a very thin silicon oxide film, such as that as thin as 4 to 8 angstroms, is used. The intermediate insulating film 50 is formed by a natural oxide film, for example, as described above. Therefore, when a voltage is applied to the floating gate FG from the control gate CG, charges (electrons) can pass through the intermediate insulating film 50 by direct tunneling. Therefore, the intermediate insulating film 50 does not have any great effect on the data writing characteristics or data erasing characteristics.

When the intermediate insulating film 50 causes the transition of the first and second floating gate parts. FG1 and FG2 from an amorphous state to a polycrystal state, the growth of a crystal gain boundary is divided at a point where the intermediate insulating film 50 is provided. Therefore, the size of the crystal gains of the first floating gate part FG1 according to the first embodiment are small, as compared with a case where the intermediate insulating film 50 is not provided. That is, the presence of the intermediate insulating film 50 between the first and second floating gate parts FG1 and FG2 distinguishes the size of the crystal gains of the first floating gate part FG1 from those of the second floating gate part FG2. That is, the intermediate insulating film 50 acts as a boundary between the first and second floating gate parts FG1 and FG2, and distinguishes, therefor, the size of the crystal gains of the first floating gate part FG1 and that of the crystal gains of the second floating gate part FG2 from each other at the intermediate insulating film 50.

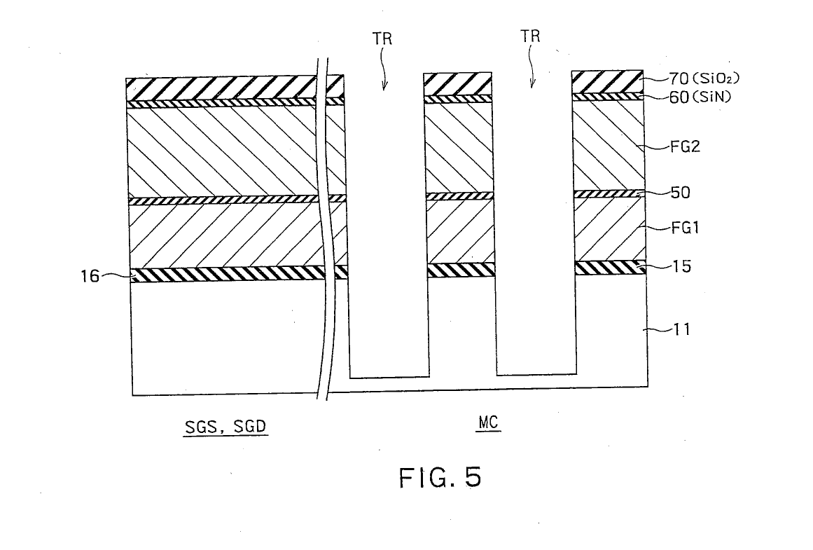

Next, as shown in FIG. 5, trenches TR are formed for forming the element isolation regions STI. The trenches TR are formed so as to penetrate the second floating gate part FG2, the intermediate insulating film 50, the first floating gate part FG1, and the tunnel gate insulating film 15, and to reach the silicon substrate 11.

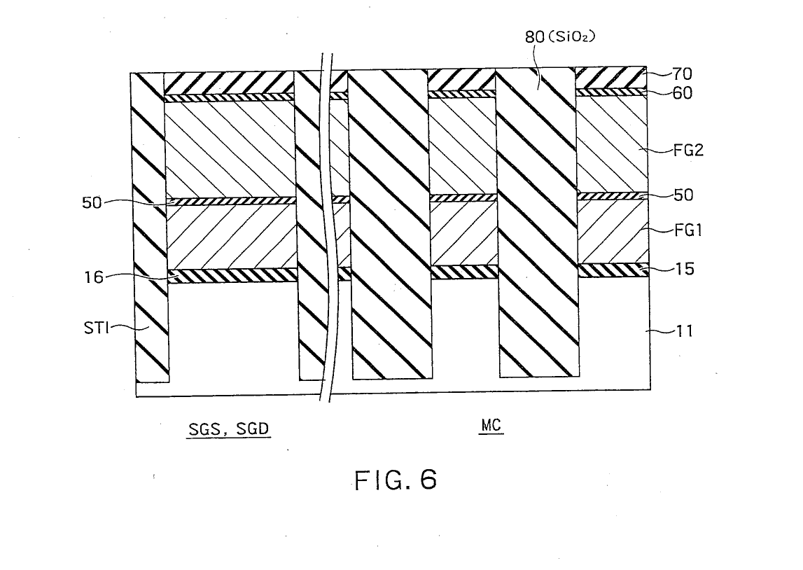

Next, as shown in FIG. 6, each of the trenches TR is filled with an insulating film 80, and the surface of the insulating film 80 is planarized. For example, an insulating film such as a silicon oxide film or silicon nitride film is used as the insulating film 80.

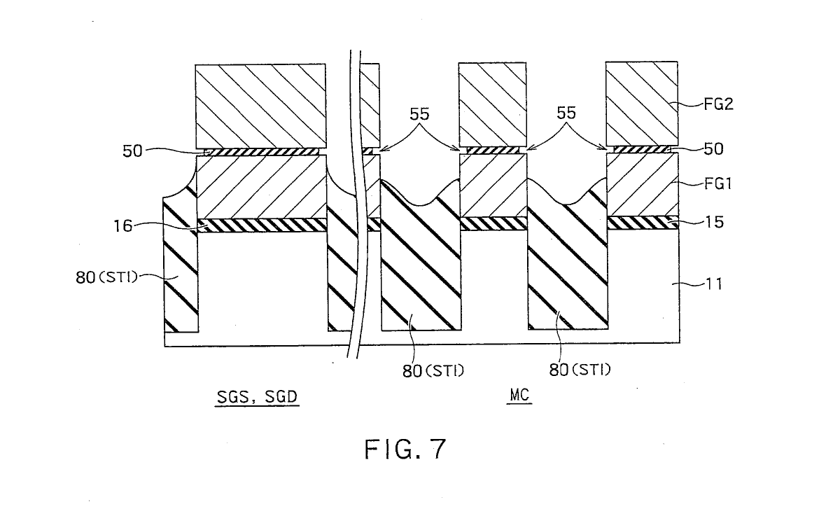

As shown in FIG. 7, the insulating film 80 is etched back. At this time, the insulating film 80 is etched back down to a position deeper (lower) than that of the intermediate insulating film 50 and shallower (higher) than that of the tunnel gate insulating film 15 until a side surface of the intermediate insulating film 50 is exposed. That is, the insulating film 80 is etched until the side surface of the intermediate insulating film 50 is exposed. Accordingly, a surface of each of the element isolation regions STI is located at a position deeper (lower) than that of the intermediate insulating film 50 and shallower (higher) than that of the tunnel gate insulating film 15. At this time, the insulating film 80 is etched back by using isotropic etching (wet etching, CDE (Chemical Dry Etching) or isotropic plasma etching, for example). The intermediate insulating film 50 exposed on the side surface of each floating gate FG is thereby etched in a lateral direction (a direction parallel to a surface of the silicon substrate 11). As a result, the recesses (constrictions) 55 are formed on the side surface of each floating gate FG as shown in FIG. 7.

Because the intermediate insulating film 50 is very thin as already described, the second floating gate part FG2 is hardly peeled off (that is, lifted off) from the intermediate insulating film 50 in a step of etching back the insulating film 80.

Recesses are also formed on gate side surfaces of the select gate transistors SGS and SGD. These recesses do not have any great effect on the characteristics of the select gate transistors SGS and SGD.

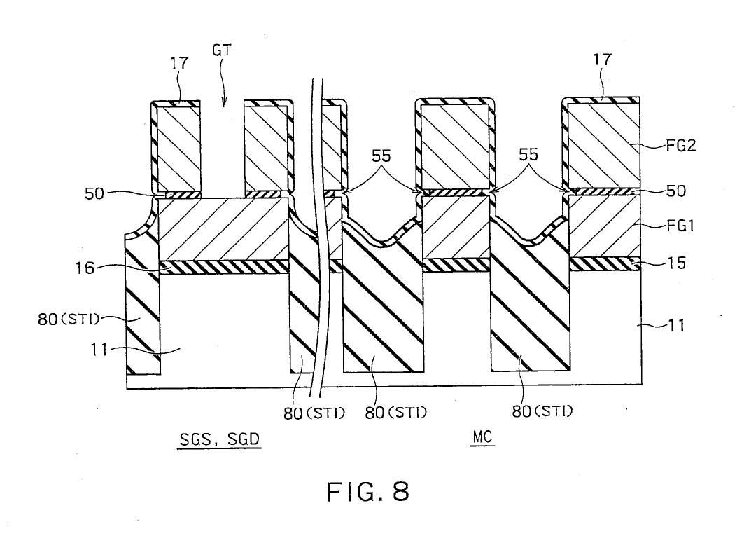

As shown in FIG. 8, the IPD film 17 is deposited on an inside surface of each trench TR, and a gate trench GT is formed by eliminating (etching away) a part of the IPD film 17 provided in each of the select gate transistors SGS and SGD. While etching the IPD film 17 in each of the select gate transistors SGS and SGD, the intermediate insulating film 50 is used to function as an etching stopper or to detect an etching depth. For example, after etching the IPD film 17 in each of the select gate transistors SGS and SGD, the materials of the floating gate FG are subjected to over-etching. At this time, when the intermediate insulating film 50 is not provided, the gate trench GT obtained by etching the IPD film 17 possibly reaches and even penetrates the gate insulating film 16. On the other hand, according to the first embodiment, the intermediate insulating film 50 is provided halfway along each floating gate FG. With this configuration, when the gate trench GT obtained by the over-etching reaches the intermediate insulating film 50, an etching target material changes from the materials (polysilicon, for example) of the floating gate FG to the material (a silicon oxide film, for example) of the intermediate insulating film 50. Detecting this change in the etching target material can prevent excessive etching. As a result, according to the first embodiment, the intermediate insulating film 50 can control a depth of the gate trench GT, which makes it difficult for the gate trench GT obtained by etching the IPD film 17 to reach the gate insulating film 16. Intermediate parts of the intermediate insulating film 50 are eliminated by the over-etching.

Next, the material of the control gate CG is deposited on the IPD film 17. For example, the IPD film 17 is the silicon oxide film, the silicon nitride film, or the insulating film such as the High-k film. For example, the material of the control gate CG is the conductive film made of doped polysilicon. The material of the control gate CG is filled by a depth between depths of the intermediate insulating film 50 and the tunnel gate insulating film 15 in proportion to the depth of the etch-back as described above.

Because of the formation of the recesses 55 on the side surface of each floating gate FG, the IPD film 17 is also formed to have recesses in proportion to the recesses 55. The material of the control gate CG is formed to protrude toward the side surface of the floating gate FG via the IPD film 17 in proportion to the recesses 55.

In each of the select gate transistors SGS and SGD, the material of the control gate CG is deposited on the floating gate FG and electrically connected to the floating gate FG in the gate trench GT obtained by eliminating the IPD film 17.

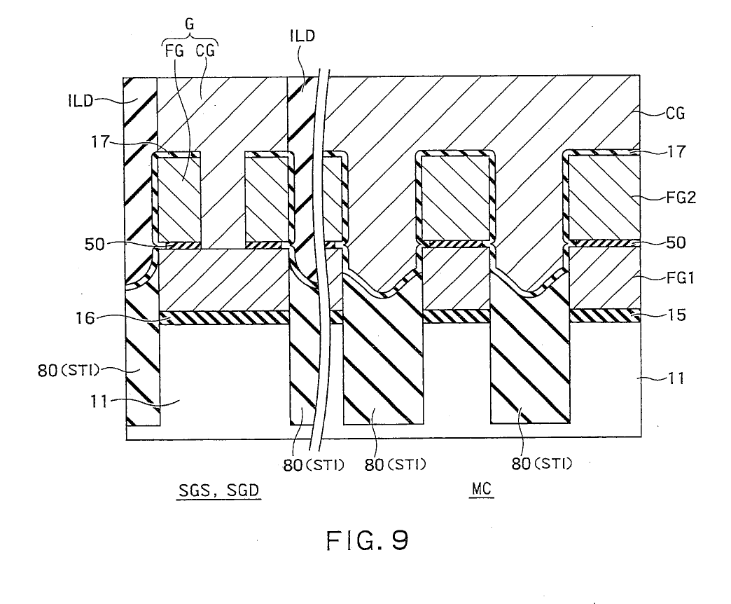

Furthermore, the material of the control gate CG is processed by using a lithography technique and an etching technique, thereby forming the control gate CG as shown in FIG. 9.

In this way, in each of the select gate transistors SGS and SGD, the control gate CG is electrically connected to the floating gate FG and the control gate CG and the floating gate FG function as one gate electrode G in the portion from which the IPD film 17 is eliminated.

Thereafter, an interlayer dielectric film ILD and wires such as the bit lines BL are formed, thus completing the NAND flash EEPROM according to the first embodiment.

According to the first embodiment, the intermediate insulating film 50 is inserted into each floating gate FG, and the recesses 55 are formed on the side surface of the floating gate FG in the portions corresponding to the intermediate insulating film 50 by the isotropic etching. The control gate CG protrudes toward the side surface of the floating gate FG via the IPD film 17 in proportion to the recesses 55. This can increase the opposed area by which the floating gate FG is opposed to the control gate CG and, therefore increase the coupling capacitance ratio Cr. Because the control gate CG is formed shallow between the adjacent floating gates FG, it is possible to suppress the occurrence of seams or voids in the control gate CG.

The intermediate insulating film 50 not only increases the coupling capacitance ratio Cr in each memory cell MC but also is used to function as an etching stopper or function to detect the etching depth in each of the select gate transistors SGS and SGD. According to the first embodiment, it is thereby possible to improve not only the characteristics of the memory cells MC but also the reliability of the select gate transistors SGS and SGD.

### Second Embodiment

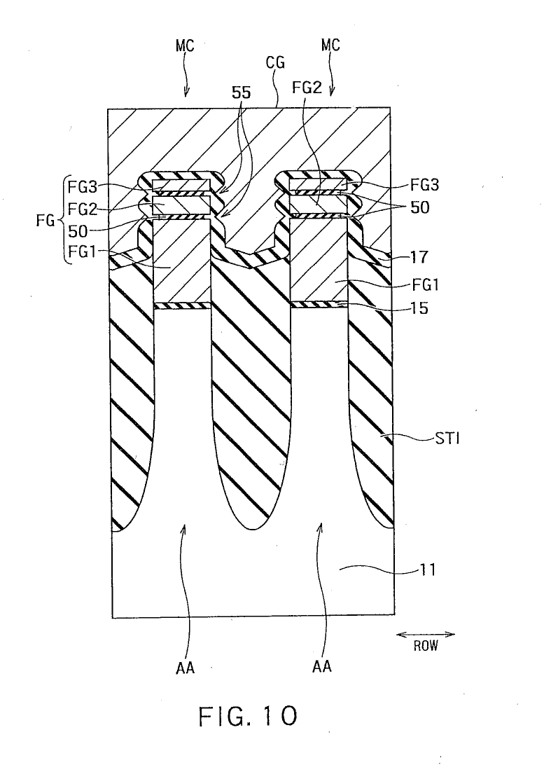

FIG. 10 is a cross-sectional view showing a configuration of memory cells MC in a NAND flash EEPROM according to a second embodiment. The second embodiment differs from the first embodiment in that each floating gate FG includes a plurality of intermediate insulating films 50. Configurations of the second embodiment other than this difference can be identical to corresponding configurations of the first embodiment.

For example, in FIG. 10, the floating gate FG includes two intermediate insulating films 50. The two intermediate insulating films 50 divide the floating gate FG into first to third floating gate parts FG1 to FG3. The two intermediate insulating films 50 are recessed in comparison with the side surfaces of the first to third floating gate parts FG1 to FG3 on the side surface of the floating gate FG. That is, on the side surface of the floating gate FG, the recesses (constrictions) 55 as many as the intermediate insulating films 50, that is, two recesses 55 are formed.

According to the second embodiment, it is thereby possible to further increase the opposed area by which the floating gate FG is opposed to the control gate CG and further increase the coupling capacitance ratio Cr. The control gate CG can be thereby formed shallower between the adjacent floating gates FG than that according to the first embodiment. Therefore, it is possible to suppress the occurrence of seams or voids in the control gate CG more effectively. Furthermore, the second embodiment can achieve effects identical to those of the first embodiment.

The number of the intermediate insulating films 50 can be further increased. In general terms, one floating gate FG can include first to nth floating gate parts FG1 to FGn, where n is an integer larger than 2, and (n−1) intermediate insulating films 50 provided between the first to nth floating gate parts FG1 to FGn. The (n−1) intermediate insulating films 50 are recessed in comparison with the side surfaces of the first to nth floating gate parts FG1 to FGn on the side surface of the floating gate FG. As can be understood, the further increased number of intermediate insulating films 50 can further increase the opposed area by which the floating gate FG is opposed to the control gate CG, and further increase the coupling capacitance ratio Cr.

In a manufacturing method of the second embodiment, materials of the first to the nth floating gate parts FG1 to FGn and materials of (n−1) intermediate insulating films 50 are deposited alternatively on the first insulating film 15, after formation of the first insulating film 15.

Next, a trench TR (c.f. FIG. 5) is formed so as to penetrate the materials of the first to the nth floating gate parts FG1 to FGn and the materials of (n−1) intermediate insulating films 50. As a result, the floating gate FG including the first to the nth floating gate parts FG1 to FGn is formed.

The other processes after formation of the floating gate FG of the second embodiment can be same as the corresponding processes of the first embodiments. In this way, the memory according to the second embodiment can be completed.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

For example, these embodiments have been described about using n-FET as memory cells MC, but it can be using p-FET as memory cells MC.

1. A semiconductor storage device comprising:
a semiconductor substrate;
a first insulating film on the semiconductor substrate;
a charge storage layer including a first part on the first insulating film, an intermediate insulating film on the first part, and a second part on the intermediate insulating film, the charge storage layer being capable of storing electric charges;
a second insulating film on an upper surface and a side surface of the charge storage layer; and
a control gate opposed to the upper surface and the side surface of the charge storage layer via the second insulating film, the control gate controlling a voltage of the charge storage layer, wherein
the intermediate insulating film is recessed in comparison with side surfaces of the first and the second parts on the side surface of the charge storage layer.

2. The device of claim 1, wherein the control gate is provided at a position lower than a position of the intermediate insulating film and higher than a position of the first insulating film on the side surface of the charge storage layer.

3. The device of claim 1, wherein
the second insulating film is recessed together with the intermediate insulating film on the side surface of the charge storage layer, and
the control gate protrudes toward the side surface of the charge storage layer in proportion to the intermediate insulating film.

4. The device of claim 2, wherein
the second insulating film is recessed together with the intermediate insulating film on the side surface of the charge storage layer, and
the control gate protrudes toward the side surface of the charge storage layer in proportion to the intermediate insulating film.

5. The device of claim 1, wherein
the charge storage layer further includes first to nth parts, where n is an integer larger than 2, and (n−1) intermediate insulating films provided between the first to the nth parts, and
the (n−1) intermediate insulating films are recessed in comparison with side surfaces of the first to the nth parts on the side surface of the charge storage layer.

6. The device of claim 2, wherein
the charge storage layer further includes first to nth parts, where n is an integer larger than 2, and (n−1) intermediate insulating films provided between the first to the nth parts, and
the (n−1) intermediate insulating films are recessed in comparison with side surfaces of the first to the nth parts on the side surface of the charge storage layer.

7. The device of claim 3, wherein
the charge storage layer further includes first to nth parts, where n is an integer larger than 2, and (n−1) intermediate insulating films provided between the first to the nth parts, and
the (n−1) intermediate insulating films are recessed in comparison with side surfaces of the first to the nth parts on the side surface of the charge storage layer.

8. The device of claim 1, wherein the first and the second parts provided on and under the intermediate insulating film have different crystal grain boundaries at the intermediate insulating film serving as a border.

9. The device of claim 2, wherein the first and the second parts, where k is any one of integers 1 to n, provided on and under the intermediate insulating film have different crystal grain boundaries at the intermediate insulating film serving as a border.

10. The device of claim 3 wherein the first and the second parts, where k is any one of integers 1 to n, provided on and under the intermediate insulating film have different crystal grain boundaries at the intermediate insulating film serving as a border.

11. The device of claim 5, wherein the (n−1)th and the nth parts, where k is any one of integers 1 to n, provided on and under the intermediate insulating film have different crystal grain boundaries at the intermediate insulating film serving as a border.

12. The device of claim 1, wherein the semiconductor storage device is a NAND flash EEPROM.

13. A method of manufacturing a semiconductor storage device comprising:
forming a first insulating film on a semiconductor substrate;
depositing a material of a first floating gate part, a material of an intermediate insulating film, and a material of a second floating gate part on the first insulating film;
forming a floating gate including the first floating gate part and the second floating gate part by forming a trench for element isolation in such a manner that the trench penetrates the material of the second floating gate part, the material of the intermediate insulating film, and the material of the first floating gate part;
filling the trench with an element-isolation insulating film;
recessing a side surface of the intermediate insulating film in comparison with a side surface of the floating gate by isotropically etching the element-isolation insulating film until the side surface of the intermediate insulating film is exposed;
forming a second insulating film on an upper surface and the side surface of the floating gate; and
forming a control gate on the second insulating film.

14. The method of claim 13, further comprising:
forming a gate trench by eliminating a part of the second insulating film and by etching the second floating gate part before forming the control gate, wherein
a depth of the gate trench is controlled by the intermediate insulating film, and
the control gate is connected to the second floating gate part in the gate trench.

15. The method of claim 13, wherein
the first floating gate part, the second floating gate part and the control gate, which is insulated from the first and the second floating gate parts by the second insulating film, are included in a memory cell, and
the first floating gate part, the second floating gate part and the control gate, which is electrically connected to the first and the second floating gate parts by the gate trench, are included in a select gate transistor configured to be operated when the memory cell is selected.

16. The method of claim 14, wherein
the first floating gate part, the second floating gate part and the control gate, which is insulated from the first and the second floating gate parts by the second insulating film, are included in a memory cell, and
the first floating gate part, the second floating gate part and the control gate, which is electrically connected to the first and the second floating gate parts by the gate trench, are included in a select gate transistor configured to be operated when the memory cell is selected.

17. The method of claim 13, wherein
After forming the first insulating film, materials of a first to a nth floating gate parts, where n is an integer larger than 2, and materials of (n−1) intermediate insulating films provided between the first to the nth floating gate parts are deposited on the first insulating film,
the trench penetrates the materials of the first to the nth floating gate parts and the materials of (n−1) intermediate insulating films, and
the floating gate includes the first to the nth floating gate parts.

18. The method of claim 13, wherein the semiconductor storage device is a NAND flash EEPROM.
